(19) United States
(12) Patent Application Publication
(10) Pub. No.: US 2024/0339454 A1
(43) Pub. Date: Oct. 10, 2024

(54) STANDARD CELLS, INTEGRATED CIRCUITS INCLUDING THE SAME AND DESIGN METHODS THEREOF

(71) Applicant: Samsung Electronics Co., Ltd., Suwon-si (KR)

(72) Inventors: Hyunchul HWANG, Suwon-si (KR); Dae Seong LEE, Suwon-si (KR)

(73) Assignee: Samsung Electronics Co., Ltd., Suwon-si (KR)

(21) Appl. No.: 18/583,125

(22) Filed: Feb. 21, 2024

(30) Foreign Application Priority Data
Apr. 5, 2023 (KR) 10-2023-0044976
Jun. 20, 2023 (KR) 10-2023-0078786

(51) Int. Cl. H01L 27/092; G06F 30/392; H01L 29/06; H01L 29/423; H01L 29/775; H01L 29/786

(52) U.S. Cl. CPC H01L 27/0922; G06F 30/392; H01L 29/0673; H01L 29/42392; H01L 29/775; H01L 29/78696

(57) ABSTRACT

A standard cell includes a plurality of regions, which includes a first region including a first active region extending in a first direction and having a first width, a second region including a second active region extending in the first direction and having a second width greater than the first width, and a first gate electrode extending in a second direction perpendicular to the first direction, and a first transistor corresponding to at least a portion of the first active region and the first gate electrode includes a first channel having the first width, a second transistor corresponding to at least a portion of the second active region and the first gate electrode includes a second channel having the second width, and the first region and the second region contact in the second direction and have the same width with respect to the second direction.

### CROSS-REFERENCE TO RELATED APPLICATIONS

This application claims priority under 35 U.S.C. § 119 to Korean Patent Application Nos. 10-2023-0044976 filed on Apr. 5, 2023, and 10-2023-0078786 filed on Jun. 20, 2023, respectively, in the Korean Intellectual Property Office, the disclosures of each of which are incorporated by reference herein in their entireties.

### BACKGROUND

Example embodiments of the present inventive concepts described herein relate to standard cells and integrated circuits including the same.

A standard cell may be utilized as a minimum unit for designing integrated circuits. For example, the standard cell may have a uniform height based on the distance between power lines.

Conventionally, one standard cell generally has a height corresponding to the distance between two power lines. However, as various integrated circuit devices are used, the need to use a standard cell including a region between three or more power lines is increasing.

In addition, as the types of devices implemented in the standard cell increase, cases in which transistors having different channel widths are disposed adjacent to each other in one standard cell are increasing.

However, when transistors having different channel widths are disposed adjacent to each other, performance of the corresponding transistors and neighboring transistors may decrease due to a local layout effect (LLE), etc.

### SUMMARY

Example embodiments of the present inventive concepts provide a standard cell including transistors having different channel widths and disposed in distinct regions.

According to some example embodiments, a standard cell including a plurality of regions includes a first region including a first active region extending in a first direction and having a first width, a second region including a second active region extending in the first direction and having a second width greater than the first width, and a first gate electrode extending in a second direction perpendicular to the first direction, wherein a first transistor corresponding to at least a portion of the first active region and the first gate electrode includes a first channel having the first width, wherein a second transistor corresponding to at least a portion of the second active region and the first gate electrode includes a second channel having the second width, and wherein the first region and the second region contact in the second direction and have the same width with respect to the second direction.

According to some example embodiments, an integrated circuit including a standard cell includes a first power line extending in a first direction, a second power line and a third power line extending in the first direction and spaced apart from the first power line by a first distance in a second direction perpendicular to the first direction, and a standard cell including regions between the first power line, the second power line, and the third power line, wherein the standard cell includes a first active region extending in the first direction and having a first width in a first region between the first power line and the second power line, a second active region extending in the first direction and having a second width greater than the first width in a second region between the first power line and the third power line, and a first gate electrode extending in the second direction, wherein a first transistor corresponding to at least a portion of the first active region and the first gate electrode includes a first channel having the first width, and wherein a second transistor corresponding to at least a portion of the second active region and the first gate electrode includes a second channel having the second width.

According to some example embodiments, a method of designing an integrated circuit including a standard cell includes receiving input data defining the integrated circuit, identifying at least one standard cell among a plurality of standard cells included in a standard cell library based on the input data, performing placement and routing on the identified at least one standard cell based on the input data, generating output data defining the integrated circuit based on a result of the placement and routing, and designing the integrated circuit based on the output data, and the at least one standard cell includes a first region including a first active region extending in a first direction and having a first width, a second region including a second active region extending in the first direction and having a second width greater than the first width, and a first gate electrode extending in a second direction perpendicular to the first direction, a first transistor formed by the first gate electrode and at least a portion of the first active region includes a first channel having the first width, a second transistor formed by the first gate electrode and at least a portion of the second active region includes a second channel having the second width, and the first region and the second region contact in the second direction and have the same width with respect to the second direction.

### BRIEF DESCRIPTION OF THE FIGURES

The above and other objects and features of the present inventive concepts will become apparent by describing in detail some example embodiments thereof with reference to the accompanying drawings.

FIG. 1A illustrates a standard cell according to some example embodiments.

FIG. 1B illustrates a layout of a standard cell 100A according to some example embodiments.

FIG. 2 illustrates a cross section of a standard cell of FIG. 1B cut along line A-A′ according to some example embodiments.

FIG. 3 illustrates a cross section of a standard cell of FIG. 1B cut along line B-B′ according to some example embodiments.

FIG. 4A illustrates an integrated circuit implemented through a standard cell, according to some example embodiments.

FIG. 4B illustrates a layout of an integrated circuit of FIG. 4A according to some example embodiments.

FIG. 5 illustrates a layout of a standard cell 100B according to some example embodiments.

FIG. 6 illustrates a layout of a standard cell 100C according to some example embodiments.

FIG. 7 is a block diagram of a semiconductor device according to some example embodiments.

FIG. 8 is a flowchart illustrating an example of an operation of a semiconductor device of FIG. 7 according to some example embodiments.

### DETAILED DESCRIPTION

Hereinafter, example embodiments of the present inventive concepts will be described more fully with reference to the accompanying drawings, in which some example embodiments of the inventive concepts are shown. As those skilled in the art would realize, the described example embodiments may be modified in various different ways, all without departing from the spirit or scope of the present inventive concepts.

Accordingly, the drawings and description are to be regarded as illustrative in nature and not restrictive. Like reference numerals designate like elements throughout the specification. The sequence of operations or steps are not limited to the order presented in the claims or figures unless specifically indicated otherwise. The order of operations or steps may be changed, several operations or steps may be merged, a certain operation or step may be divided, and a specific operation or step may not be performed.

As used herein, the singular forms “a” and “an” are intended to include the plural forms as well, unless the context clearly indicates otherwise. Although the terms first, second, and the like may be used herein to describe various elements, components, steps and/or operations, these terms are only used to distinguish one element, component, step or operation from another element, component, step, or operation.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

In addition, it will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

Furthermore, when the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

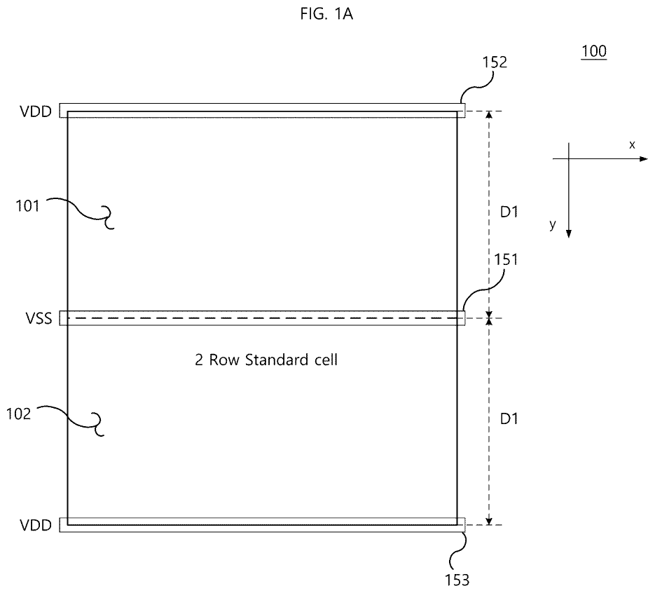

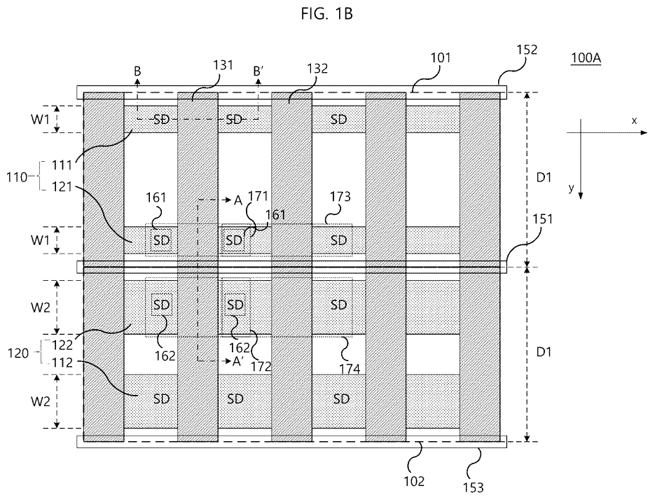

FIG. 1A illustrates a standard cell according to some example embodiments. FIG. 1B illustrates a layout of a standard cell 100A according to some example embodiments.

Referring to FIGS. 1A and 1B together, a standard cell 100 according to some example embodiments may include a first region 101 and a second region 102 having the same width (or height) D1. For example, the standard cell 100 may include the first region 101 and the second region 102, which are formed to be adjacent to each other and have the same width D1 in a second direction (e.g., y-direction).

Referring to FIG. 1A, the standard cell 100 according to some example embodiments may include a first power line 151, a second power line 152, and a third power line 153, which extend in a first direction (e.g., x-direction) and are spaced apart from each other in the second direction.

For example, the standard cell 100 may include the first power line 151 extending in the first direction (e.g., x-direction) from an edge in which the first region 101 and the second region 102 contact each other. For example, the standard cell 100 may include the second power line 152 extending in the first direction from an edge parallel to an edge of the first region 101 adjacent to the second region 102. For example, the standard cell 100 may include the third power line 153 extending in the first direction from an edge parallel to an edge of the second region 102 adjacent to the first region 101.

According to some example embodiments, the first region 101 of the standard cell 100 may be defined as a region between the first power line 151 and the second power line 152. Also, the second region 102 may be defined as a region between the first power line 151 and the third power line 153.

For example, when viewing the standard cell 100 in a third direction (e.g., z-axis direction) perpendicular to the first and second directions, some of edges of the first region 101 may overlap with the first power line 151 and the second power line 152. For example, when viewing the standard cell 100 in the third direction, some of edges of the second region 102 may overlap the first power line 151 and the third power line 153.

In some example embodiments, the standard cell 100 may include the regions 101 and 102 between the first power line 151 and the second power line 152 and between the first power line 151 and the third power line 153, respectively. Accordingly, the standard cell 100 according to some example embodiments may be referred to as a multi-row standard cell including regions among three or more power lines. For example, the standard cell 100 according to some example embodiments may be understood as a 2-row standard cell including two regions among three power lines, but example embodiments are not limited thereto.

According to some example embodiments, an integrated circuit including the standard cell 100 may include the first power line 151, the second power line 152, and the third power line 153 which are formed on a semiconductor substrate. Furthermore, the integrated circuit may include the standard cell 100 including regions among the first power line 151, the second power line 152, and the third power line 153.

According to some example embodiments, the first power line 151 and the second power line 152 may be disposed to be spaced apart from each other with a distance of the specified width D1 in the second direction (e.g., y-direction). In some example embodiments, the first power line 151 and the third power line 153 may also be disposed to be spaced apart from each other with the distance of the specified width D1 in the second direction.

For example, the second power line 152 and the third power line 153 may be disposed to be spaced apart from the first power line 151 with the same distance D1 in the second direction.

Furthermore, the first region 101 and the second region 102 of the standard cell 100 may have the same width D1 in the second direction.

For example, each width D1 of the first region 101 and the second region 102 may be understood as 200 nm, but example embodiments are not limited thereto.

Through this, the standard cell 100 according to some example embodiments may reduce at least a part of time, cost, and power consumed for placement and routing of the standard cell 100 in integrated circuit design.

According to some example embodiments, the first power line 151, the second power line 152, and the third power line 153 may apply one of a drain voltage VDD or a source voltage VSS with respect to at least a portion of the first region 101 and the second region 102.

For example, the second power line 152 and the third power line 153 may apply the same voltage to at least a portion of the first region 101 and the second region 102.

For example, the second power line 152 and the third power line 153 may apply the drain voltage VDD to transistors formed in a portion of the first region 101 and the second region 102. For example, the first power line 151 may apply the source voltage VSS to transistors formed in a portion of the first region 101 and the second region 102.

For example, the second power line 152 and the third power line 153 may apply the source voltage VSS to transistors formed in the portion of the first region 101 and the second region 102. For example, the first power line 151 may apply the drain voltage VDD to transistors formed in a portion of the first region 101 and the second region 102.

Through this, the standard cell 100 may operate at least some of a plurality of transistors formed therein.

However, the voltages applied to the first region 101 and the second region 102 through the first power line 151, the second power line 152, and the third power line 153 are not limited to the example embodiments described above.

Referring to FIG. 1B, the standard cell 100A may include a first active region 110 and a second active region 120, which have different widths and are formed in the first region 101 or the second region 102.

For example, the standard cell 100A may include the first active region 110 formed to have a first width W1 within the first region 101. In addition, the standard cell 100A may include the second active region 120 formed to have a second width W2 within the second region 102. The first active region 110 and the second active region 120 may be formed to extend in the first direction (e.g., x-direction).

According to some example embodiments, each of the first active region 110 and the second active region 120 may include a PMOS region and an NMOS region. For example, the first active region 110 may include a first PMOS region 111 and a first NMOS region 121 spaced apart from each other in the second direction (e.g., y-direction). For example, the second active region 120 may include a second PMOS region 112 and a second NMOS region 122 spaced apart from each other in the second direction.

For example, the standard cell 100A of FIG. 1B may be understood as an example of the standard cell 100 of FIG. 1A.

In some example embodiments, the standard cell 100A may include the first PMOS region 111 and the first NMOS region 121 extending in the first direction (e.g., x-direction) with the first width W1 within the first region 101. For example, the first PMOS region 111 and the first NMOS region 121 may be disposed to be spaced apart from each other in the second direction (e.g., y-direction) perpendicular to the first direction.

In some example embodiments, the standard cell 100A may include the second PMOS region 112 and the second NMOS region 122 extending in the first direction (e.g., x-direction) with the second width W2 greater than the first width W1 within the second region 102. For example, the second PMOS region 112 and the second NMOS region 122 may be disposed to be spaced apart from each other in the second direction (e.g., y-direction).

The first NMOS region 121 and the second NMOS region 122 may be formed to be adjacent to the first power line 151. In some example embodiments, the first PMOS region 111 may be formed adjacent to the second power line 152, and the second PMOS region 112 may be formed adjacent to the third power line 153.

Furthermore, the standard cell 100A may include a first gate electrode 131 extending in the second direction. For example, the standard cell 100A may include the first gate electrode 131 crossing the first region 101 and the second region 102.

For example, the standard cell 100A may include the first gate electrode 131 crossing the first PMOS region 111, the first NMOS region 121, the second PMOS region 112, and the second NMOS region 122 in the second direction.

For example, each of the first PMOS region 111, the first NMOS region 121, the second PMOS region 112, and the second NMOS region 122 may include a source-drain region SD formed on both sides of the first gate electrode 131.

For example, the first NMOS region 121 may include first source-drain regions 161 formed on both sides of the first gate electrode 131. In addition, the second NMOS region 122 may include second source-drain regions 162 formed on both sides of the first gate electrode 131.

According to some example embodiments, at least a portion of the first active region 110 and the first gate electrode 131 may form a first transistor 171. For example, at least a portion of the first NMOS region 121 and the first gate electrode 131 may form the first transistor 171.

In some example embodiments, at least a portion of the second active region 120 and the first gate electrode 131 may form a second transistor 172. For example, at least a portion of the second NMOS region 122 and the first gate electrode 131 may form the second transistor 172.

For example, the first gate electrode 131 and the first source-drain regions 161 may form the first transistor 171. In some example embodiments, the first gate electrode 131 and the second source-drain regions 162 may form the second transistor 172.

For example, the first transistor 171 may have the same channel width as the first width W1 of the first NMOS region 121. In some example embodiments, the second transistor 172 may have the same channel width as the second width W2 of the second NMOS region 122.

Furthermore, the standard cell 100A may further include a second gate electrode 132 disposed parallel to the first gate electrode 131.

For example, the standard cell 100A may further include the second gate electrode 132 extending in the second direction (e.g., y-direction) and disposed to be spaced apart from the first gate electrode 131 in the first direction (e.g., x-direction).

The second gate electrode 132 according to some example embodiments may be formed to cross the first PMOS region 111, the first NMOS region 121, the second PMOS region 112, and the second NMOS region 122 in the second direction.

For example, each of the first PMOS region 111, the first NMOS region 121, the second PMOS region 112, and the second NMOS region 122 may include source-drain regions SD formed on both sides of the second gate electrode 132.

Furthermore, at least a portion of the first active region 110 and the second gate electrode 132 may form a third transistor 173. For example, at least a portion of the first NMOS region 121 and the second gate electrode 132 may form the third transistor 173. For example, the source-drain regions SD formed on both sides of the second gate electrode 132 of the first NMOS region 121 and the second gate electrode 132 may form the third transistor 173.

For example, some of the source-drain regions SD formed on both sides of the second gate electrode 132 may overlap some of the source-drain regions SD formed on both sides of the first gate electrode 131.

In some example embodiments, the third transistor 173 may include a third channel having the same width as the first width W1 of the first NMOS region 121.

For example, the third transistor 173 may have the same channel width (e.g., the first width W1) as the first transistor 171, and may be formed to be adjacent to the first transistor 171 in the first direction (e.g., x-direction).

In some example embodiments, the standard cell 100A may further include a fourth transistor 174 formed by the source-drain regions SD formed on both sides of the second gate electrode 132 of the second NMOS region 122 and the second gate electrode 132.

The fourth transistor 174 may include a fourth channel having the same width as the second width W2 of the second NMOS region 122.

For example, the fourth transistor 174 may have the same channel width W2 as the second transistor 172 and be formed to be adjacent to the second transistor 172 in the first direction (e.g., x-direction).

As described above, in some example embodiments, the standard cell 100A may include the transistors 171 and 173 formed in the first region 101 to have a relatively small channel width (e.g., the first width W1) and the transistors 172 and 174 formed in the second region 102 to have a relatively large channel width (e.g., the second width W2). For example, transistors formed in each region 101 or 102 may be disposed to be adjacent to each other.

For example, the standard cell 100A may include transistors having different channel widths and disposed in distinct regions 101 and 102.

Through this, in some example embodiments, the standard cell 100A may prevent performance deterioration of transistors caused when transistors having different channel widths are formed adjacent to each other.

Furthermore, in some example embodiments, the second transistor 172 may operate at a second speed higher than a first speed of the first transistor 171. In contrast, the first transistor 171 may operate while consuming less power than the second transistor 172.

Therefore, the standard cell 100A may include transistors (or elements) requiring high operating speed in the second region 102 and may include transistors (or elements) requiring low power consumption in the first region 101.

For example, the standard cell 100A may include transistors having different operating characteristics due to different channel widths in the distinct region 101 or 102.

Through this, in some example embodiments, the standard cell 100A may control each of the regions 101 and 102 that are distinguished from each other based on the characteristics of the transistors. Furthermore, the standard cell 100A according to some example embodiments may increase control efficiency with respect to a plurality of transistors.

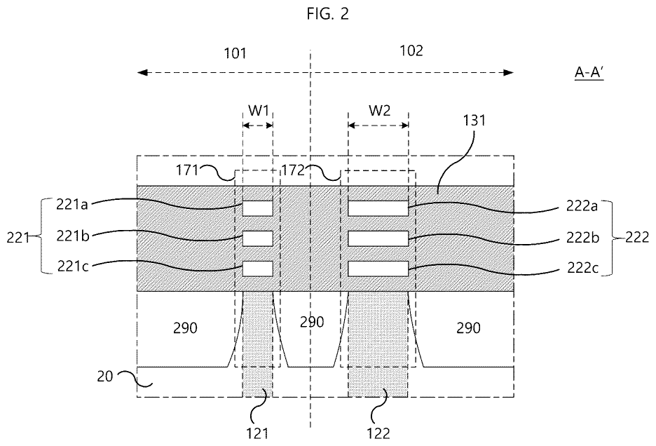

FIG. 2 illustrates a cross section of a standard cell of FIG. 1B cut along line A-A′ according to some example embodiments.

Referring to FIG. 2, transistors formed in the standard cell 100A according to some example embodiments may include nanosheets forming respective channels. For example, the standard cell 100A may include nanosheets that operate as a channel of each of a plurality of transistors formed in the standard cell 100A.

The first transistor 171 may include a first nanosheet 221 formed to have the first width W1 in a region of the first gate electrode 131 corresponding to the first NMOS region 121. For example, the first nanosheet 221 may be understood as a channel through which charges move when a voltage is applied to the first transistor 171 through the first gate electrode 131.

In some example embodiments, the second transistor 172 may include a second nanosheet 222 formed to have the second width W2 greater than the first width W1 in a region of the first gate electrode 131 corresponding to the second NMOS region 122. For example, the second nanosheet 222 may be understood as a channel through which charges move when a voltage is applied to the second transistor 172 through the first gate electrode 131.

For example, the first transistor 171 may include a first channel formed to have the first width W1 through the first nanosheet 221. In some example embodiments, the second transistor 172 may include a second channel formed to have the second width W2 through the second nanosheet 222.

Accordingly, in some example embodiments, the first transistor 171 may operate while consuming relatively less power than the second transistor 172. In addition, the second transistor 172 may operate at a relatively higher speed than the first transistor 171.

Also, referring to FIGS. 1B and 2 together, in some example embodiments, the third transistor 173 may include a third nanosheet having the first width W1 and forming a third channel of the third transistor 173. In some example embodiments, the fourth transistor 174 may include a fourth nanosheet having the second width W2 and forming a fourth channel of the fourth transistor 174.

For example, the transistors 171, 172, 173, and 174 having different channel widths (or operating characteristics) may be disposed in the distinct regions 101 and 102 in the standard cell 100A.

Through this, the standard cell 100A according to some example embodiments may prevent performance deterioration of transistors caused by adjacent arrangement of transistors having different channel widths.

Furthermore, each of the first nanosheet 221 and the second nanosheet 222 may include a plurality of nanosheets. For example, the first nanosheet 221 may include a 1-1 nanosheet 221a, a 1-2 nanosheet 221b, and a 1-3 nanosheet 221c disposed to be spaced apart from each other. In some example embodiments, the second nanosheet 222 may include a 2-1 nanosheet 222a, a 2-2 nanosheet 222b, and a 2-3 nanosheet 222c disposed to be spaced apart from each other.

For example, the number or spacing of the plurality of nanosheets included in each of the first nanosheet 221 and the second nanosheet 222 may be determined by the width of a channel implemented through each of the nanosheets 221 and 222.

According to some example embodiments, the first nanosheet 221 and the second nanosheet 222 may be formed to be surrounded by the first gate electrode 131. Accordingly, in some example embodiments, the first transistor 171 and the second transistor 172 may be understood to have a gate all around (GAA) structure.

In some example embodiments, the plurality of nanosheets 221a, 221b, 221c, 222a, 222b, and 222c forming each of the first nanosheet 221 and the second nanosheet 222 may be formed to be surrounded by the first gate electrode 131 within the first gate electrode 131. Accordingly, the first transistor 171 and the second transistor 172 may be understood as having a multi-bridge channel FET (MBCFET) structure.

For example, the plurality of nanosheets 221a, 221b, 221c, 222a, 222b, and 222c forming each of the first nanosheet 221 and the second nanosheet 222 have a width of 25 nm to 45 nm. However, the width of each of the plurality of nanosheets 221a, 221b, 221c, 222a, 222b, and 222c are not limited to the above example embodiment.

Through this configuration, the standard cell 100A according to some example embodiments may improve the operating speed of the plurality of transistors (e.g., the first transistor 171 and the second transistor 172).

According to some example embodiments, the first nanosheet 221 and the second nanosheet 222 may be formed to protrude from one surface of a substrate 20 toward the first gate electrode 131. Furthermore, at least a portion of the first nanosheet 221 and the second nanosheet 222 protruding from the substrate 20 may contact the first gate electrode 131. Accordingly, the first transistor 171 and the second transistor 172 may be understood as having a FinFET structure.

However, the structures of the first transistor 171 and the second transistor 172 are not limited to the above example embodiments, and may be understood as having various field effect transistor (FET) structures.

In addition, the standard cell 100A according to some example embodiments may further include an element isolation pattern 290 electrically isolating a plurality of transistors. For example, the standard cell 100A may include the element isolation pattern 290 electrically isolating the first transistor 171 and the second transistor 172.

For example, the element isolation pattern 290 may be formed through a shallow trench isolation (STI) process. In some example embodiments, the element isolation pattern 290 may be formed through a deep trench isolation (DTI) process.

In addition, for example, the element isolation pattern 290 may be formed of oxide and/or polysilicon.

However, the type of process for forming the element isolation pattern 290 or the material of the element isolation pattern 290 are not limited to the above example embodiments.

Through this configuration, the standard cell 100A according to some example embodiments may prevent performance degradation of the transistors caused by the transistors 171 and 172 having different channel widths being disposed adjacent to each other.

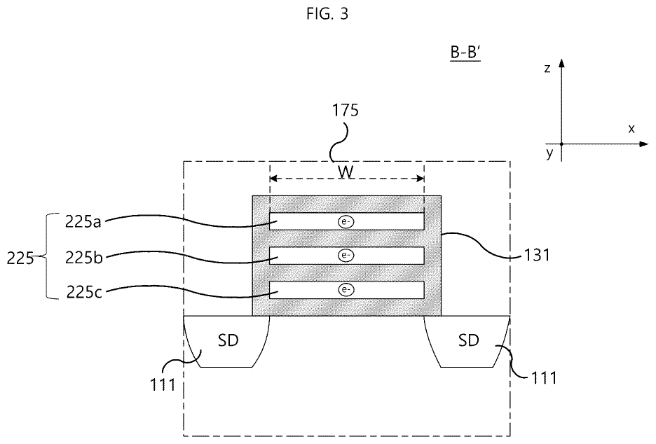

FIG. 3 illustrates a cross section of a standard cell of FIG. 1B cut along line B-B′ according to some example embodiments.

Referring to FIG. 3, the standard cell 100A according to some example embodiments may further include a fifth transistor 175 formed through at least a portion of the first PMOS region 111 and the first gate electrode 131.

For example, the standard cell 100A may include the fifth transistor 175 formed through the source-drain region SD formed on both sides of the first gate electrode 131 of the first PMOS region 111 and the first gate electrode 131.

The fifth transistor 175 according to some example embodiments may include a fifth nanosheet 225 formed in the first gate electrode 131. In more detail, the fifth transistor 175 may include the fifth nanosheet 225 formed in a region corresponding to a region of the first gate electrode 131 excluding the source-drain region SD.

For example, the fifth nanosheet 225 may be understood as a channel through which charges move between the source-drain regions SD as a voltage is applied to the fifth transistor 175 through the first gate electrode 131.

The fifth nanosheet 225 may have the specified width W in the first direction (e.g., x-direction). For example, the width W of the fifth nanosheet 225 in the first direction may be determined by the width of the first gate electrode 131 in the first direction.

Accordingly, in some example embodiments, the standard cell 100A may include the fifth transistor 175 formed by at least a portion of the first PMOS region 111 and the first gate electrode 131 and formed to have the first width W1 in the second direction (e.g., y-direction) and the specified width W in the first direction (e.g., x-direction).

In some example embodiments, the fifth nanosheet 225 may include a 5-1 nanosheet 225a, a 5-2 nanosheet 225b, and a 5-3 nanosheet 225c disposed to be spaced apart from each other.

For example, the plurality of nanosheets 225a, 225b, and 225c may be disposed to be spaced apart from each other and surrounded by the first gate electrode 131, respectively. For example, the plurality of nanosheets 225a, 225b, and 225c are spaced apart from each other in the third direction (e.g., z-direction) perpendicular to the first and second directions, and may be disposed to be surrounded by the first gate electrode 131, respectively.

Accordingly, the fifth transistor 175 may be understood to have a GAA structure or an MBCFET structure.

Through the above configurations, the standard cell 100A according to some example embodiments may improve performance of transistors formed in the standard cell 100A. For example, the standard cell 100A may reduce power consumption of transistors formed in the standard cell 100A. Furthermore, the standard cell 100A may have a minimized area.

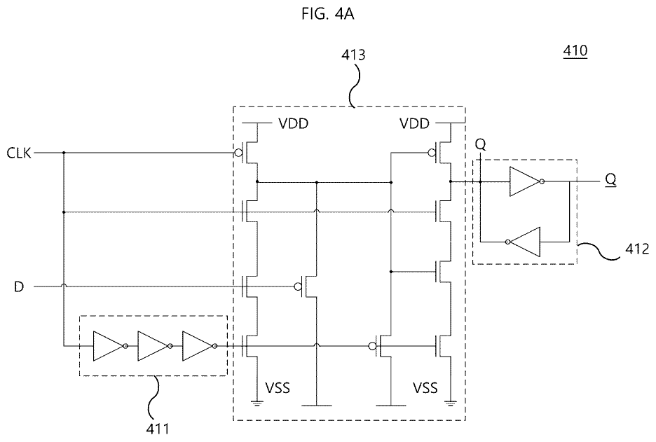

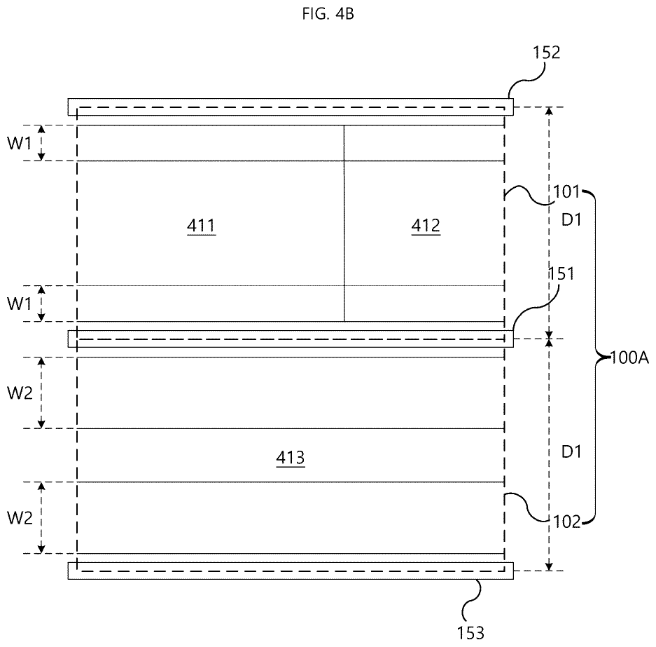

FIG. 4A illustrates an integrated circuit implemented through a standard cell, according to some example embodiments. FIG. 4B illustrates a layout of an integrated circuit of FIG. 4A according to some example embodiments.

Referring to FIGS. 4A and 4B together, an integrated circuit 410 according to some example embodiments may be implemented through the standard cell 100A having the plurality of regions 101 and 102. For example, the integrated circuit 410 may be configured through elements (or transistors) implemented in the different regions 101 and 102 of the standard cell 100A.

Referring to FIG. 4A, for example, the integrated circuit 410 may be referred to as a pulse-based flip-flop circuit. However, the integrated circuit 410 according to some example embodiments is not limited thereto, and may be understood as various types of integrated circuits that can be implemented through the standard cell 100A.

However, below, for convenience of description, the integrated circuit 410 will be described as a pulse-based flip-flop circuit.

According to some example embodiments, the integrated circuit 410 may include a first element 411 generating a pulse while having a form of an inverter chain. In some example embodiments, the integrated circuit 410 may include a second element 412 that maintains an output value of the flip-flop circuit.

Furthermore, the integrated circuit 410 may include a third element 413 that determines the delay of the flip-flop circuit. For example, the third element 413 may include a plurality of transistors.

The plurality of elements 411, 412, and 413 included in the integrated circuit 410 may have different operating characteristics.

For example, in an operation of the integrated circuit 410, the first element 411 and the second element 412 may require relatively low speed and low power consumption compared to the third element 413.

In some example embodiments, in the operation of the integrated circuit 410, the third element 413 may require relatively high speed and high power consumption compared to the first element 411 and the second element 412.

Referring to FIG. 4B, the integrated circuit 410 according to some example embodiments may be implemented using transistors having different channel widths in each of the plurality of regions 101 and 102 of the standard cell 100A.

According to some example embodiments, the first element 411 and the second element 412 may be implemented using transistors formed in the first region 101. For example, the first element 411 and the second element 412 may be formed through a plurality of transistors (e.g., the first transistor 171 of FIG. 2) formed to have the first width W1 in the first region 101.

In some example embodiments, the third element 413 may be implemented using transistors formed in the second region 102. For example, the third element 413 may be formed with a plurality of transistors (e.g., the second transistor of FIG. 2) formed to have the second width W2 greater than the first width W1 in the second region 102.

For example, the first region 101 and the second region 102 may have the same width D1 in the second direction (e.g., y-direction).

As described above, the plurality of elements forming the integrated circuit 410 according to some example embodiments may be implemented by transistors formed to have different channel widths W1 and W2 in the different regions 101 and 102 of the standard cell 100A, based on each operating characteristic (e.g., a speed or a power consumption).

Accordingly, the standard cell 100A may implement the integrated circuit 410 through elements (or transistors) that have different operating characteristics and are implemented in distinct regions.

Through this, the standard cell 100A according to some example embodiments may prevent performance deterioration of elements that occur when the elements having different operating characteristics are disposed adjacent to each other.

In some example embodiments, the standard cell 100A may implement the integrated circuit 410 by using a plurality of transistors formed to have different widths in the plurality of regions 101 and 102 having the same width D1.

Through this, the standard cell 100A according to some example embodiments may control the elements forming the integrated circuit 410 based on the characteristics of each element. Furthermore, the standard cell 100A according to some example embodiments may increase control efficiency of a plurality of elements implementing the integrated circuit 410.

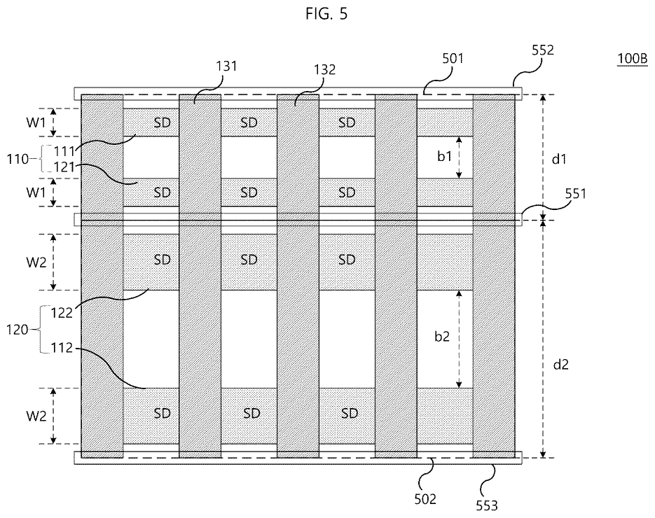

FIG. 5 illustrates a layout of a standard cell 100B according to some example embodiments.

Referring to FIG. 5, the standard cell 100B according to some example embodiments may include a first region 501 and a second region 502 having different widths d1 and d2, respectively.

For example, the standard cell 100B may be understood as an example of the standard cell 100 of FIG. 1A. Therefore, the same reference numerals are used for the same or actually the same components as those described above, and additional descriptions are omitted to avoid redundancy.

For example, the standard cell 100B may include the first region 501 having a first width d1 and the second region 502 having a second width d2 greater than the first width d1 in the second direction (e.g., y-direction). For example, the first region 501 and the second region 502 may be formed to be adjacent to each other in the second direction.

In some example embodiments, the standard cell 100B may include a first power line 551 extending in a first direction (e.g., x-direction) from an edge in which the first region 501 and the second region 502 contact each other. In addition, the standard cell 100B may include a second power line 552 extending in the first direction from an edge parallel to an edge of the first region 501 adjacent to the second region 502. In addition, the standard cell 100B may include a third power line 553 extending in the first direction from an edge parallel to an edge of the second region 502 adjacent to the first region 501.

According to some example embodiments, the first region 501 of the standard cell 100B may be defined as a region between the first power line 551 and the second power line 552. In addition, the second region 502 may be defined as a region between the first power line 551 and the third power line 553.

For example, the first power line 551 and the second power line 552 may be disposed to be spaced apart from each other with a distance of the first width d1 in the second direction. For example, the first power line 551 and the third power line 553 may also be disposed to be spaced apart from each other with a distance of the second width d2 greater than the first width d1 in the second direction.

For example, the third power line 553 has a relatively wider width (e.g., the second width d2) than the second power line 552, and may be disposed to be spaced apart from the first power line 551.

As described above, in some example embodiments, the first region 501 and the second region 502 of the standard cell 100B may have the first width d1 and the second width d2 that are different from each other in the second direction, respectively. For example, the width of the first region 501 may be understood as 100 nm, and the width of the second region 502 may be understood as 300 nm, but example embodiments are not limited thereto.

Furthermore, the standard cell 100B may include the first active region 110 having the first width W1 within the first region 501 and extending in the first direction (e.g., x-direction). For example, the standard cell 100B may include the first PMOS region 111 and the first NMOS region 121 having the first width W1 within the first region 501 and extending in the first direction (e.g., x-direction). For example, the first PMOS region 111 and the first NMOS region 121 may be disposed to be spaced apart from each other in the second direction (e.g., y-direction) perpendicular to the first direction.

Furthermore, the standard cell 100B may include the second active region 120 having the second width W2 within the second region 502 and extending in the first direction (e.g., x-direction). For example, the standard cell 100B may include the second PMOS region 112 and the second NMOS region 122 having the second width W2 greater than the first width W1 within the second region 502 and extending the first direction (e.g., x-direction). For example, the second PMOS region 112 and the second NMOS region 122 may be disposed to be spaced apart from each other in the second direction (e.g., y-direction).

The first PMOS region 111 and the first NMOS region 121 may be formed to be spaced apart from each other by a first distance b1. In some example embodiments, the second PMOS region 112 and the second NMOS region 122 may be formed to be spaced apart from each other by a second distance b2 greater than the first distance b1.

However, the size of the first distance b1 and the size of the second distance b2 are not limited to the above example embodiments, and the first distance b1 and the second distance b2 may have the same value.

Widths of the first region 501 and the second region 502 included in the standard cell 100B may be determined based on the widths of the PMOS and NMOS regions included in each region and the distance between the PMOS and NMOS regions.

For example, the standard cell 100B may include the first region 501 and the second region 502 having different widths d1 and d2 based on the widths of the PMOS and NMOS regions included in each region and the distance between the PMOS and NMOS regions.

Accordingly, the standard cell 100 according to some example embodiments may be referred to as a multi-height standard cell or a hybrid row standard cell.

Through this, the standard cell 100B according to some example embodiments may have a minimized area based on the channel width of transistors formed in each of the regions 501 and 502.

In some example embodiments, the standard cell 100B may be implemented to have a minimum area based on operating characteristics of each of elements for implementing the integrated circuit (e.g., the integrated circuit 410 of FIG. 4A).

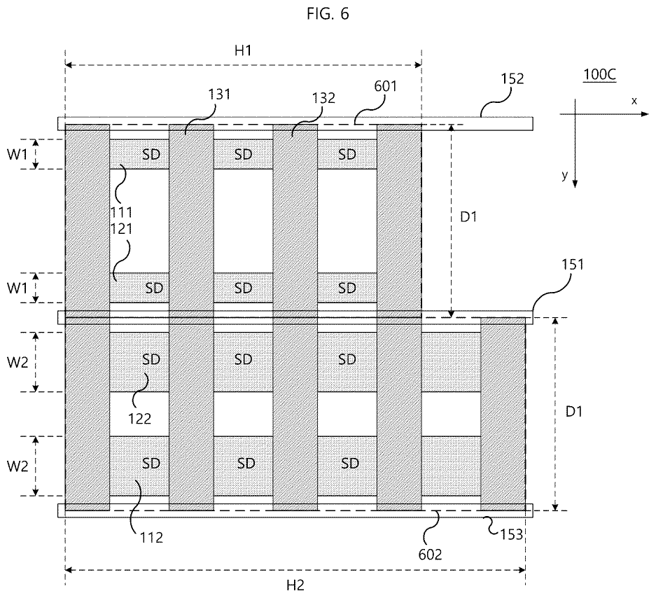

FIG. 6 illustrates a layout of a standard cell 100C according to some example embodiments.

Referring to FIG. 6, the standard cell 100C according to some example embodiments may include a first region 601 and a second region 602 having the same width D1 in the second direction (e.g., y-direction) and having different heights H1 and H2 in the first direction (e.g., x-direction).

For example, the standard cell 100C may be understood as an example of the standard cell 100 of FIG. 1A. Therefore, the same reference numerals are used for the same or actually the same components as those described above, and additional descriptions are omitted to avoid redundancy.

In some example embodiments, the first region 601 and the second region 602 may be formed to have the same width D1 in the second direction. However, the widths of the first region 601 and the second region 602 in the second direction are not limited to the above example embodiments. According to some example embodiments, the first region 601 and the second region 602 may have different widths in the second direction.

In some example embodiments, the first region 601 may have the first height H1 in the first direction, and the second region 602 may have the second height H2 greater than the first height H1 in the first direction.

According to some example embodiments, the standard cell 100C may include the first region 601 and the second region 602 having different heights H1 and H2, respectively, based on the characteristics and number of elements required to implement the integrated circuit 410.

For example, the first region 601 and the second region 602 may have different heights H1 and H2 based on the configuration of the integrated circuit (e.g., the integrated circuit 410 of FIG. 4A) implemented using the standard cell 100C.

For example, to implement the integrated circuit 410, elements (or transistors) formed by using the second PMOS region 112 and the second NMOS region 122 may be required more than elements formed through the first PMOS region 111 and the second NMOS region 122. For example, the second region 602 may be formed to have the second height H2 greater than the first height H1 of the first region 601 in the first direction (e.g., x-direction).

Through this, in some example embodiments, the standard cell 100C including the first region 601 and the second region 602 may have a polygonal shape rather than a quadrangular shape in a plan view.

However, the shape of the standard cell 100C formed by the first region 601 and the second region 602 included in the standard cell 100C is not limited to the shape illustrated in FIG. 6. The shape of the standard cell 100C according to some example embodiments may be implemented in various shapes by regions having various widths and heights based on the characteristics and number of elements required to implement the integrated circuit.

Through this, the standard cell 100C according to some example embodiments may increase the degree of integration of the integrated circuit based on the channel width and number of transistors required to implement the integrated circuit.

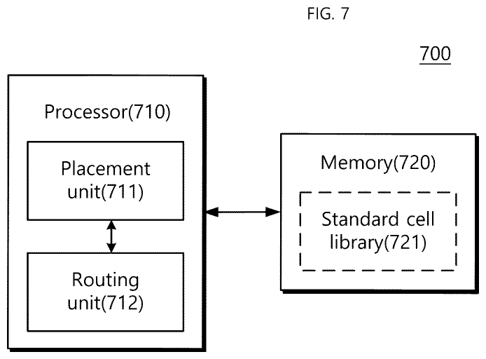

FIG. 7 is a block diagram of a semiconductor device according to some example embodiments.

Referring to FIG. 7, a semiconductor device 700 according to some example embodiments may include a processor 710 and a memory 720 connected to the processor 710.

The memory 720 may be a computer-readable storage medium and may include any storage medium that stores data and/or instructions executed by a computer. For example, the computer-readable storage medium may include volatile memories such as a RAM and a ROM, and non-volatile memories such as a flash memory, an MRAM, a PRAM, and an RRAM, but example embodiments are not limited thereto. The computer-readable storage medium may be capable of being inserted in a computer, may be integrated in the computer, or may be coupled with the computer through a communication medium such as a network and/or a wireless link.

According to some example embodiments, the memory 720 may include a standard cell library 721. The standard cell library 721 may be provided to the processor 710 from the memory 720.

The standard cell library 721 may include a plurality of standard cells. In some example embodiments, at least some of the plurality of standard cells may be understood as multi-row standard cells including a region between three or more power lines. For example, the standard cell may be understood as a unit forming the minimum unit in the design of a block, element, or chip.

According to some example embodiments, the processor 710 may include a placement unit 711 and a routing unit 712.

The processor 710 may arrange the standard cells (e.g., the standard cell 100 of FIG. 1A) by using the placement unit 711 based on the standard cell library 721 and input data defining the integrated circuit.

In some example embodiments, the processor 710 may perform signal routing on the arrangement of standard cells provided from the placement unit 711 by using the routing unit 712.

For example, in some example embodiments, when the signal routing is not successfully completed, the placement unit 711 may modify and provide an existing arrangement. Subsequently, the routing unit 712 may perform signal routing again with respect to the modified arrangement.

For example, in some example embodiments, when the signal routing is successfully completed, the routing unit 712 may generate output data defining an integrated circuit.

According to some example embodiments, the placement unit 711 and the routing unit 712 may be implemented as an integrated component. According to some example embodiments, the placement unit 711 and the routing unit 712 may be implemented as separate components.

Referring to the configuration described above, the placement unit 711 and the routing unit 712 included in the processor 710 according to some example embodiments may perform placement and routing for integrated circuits using the standard cells.

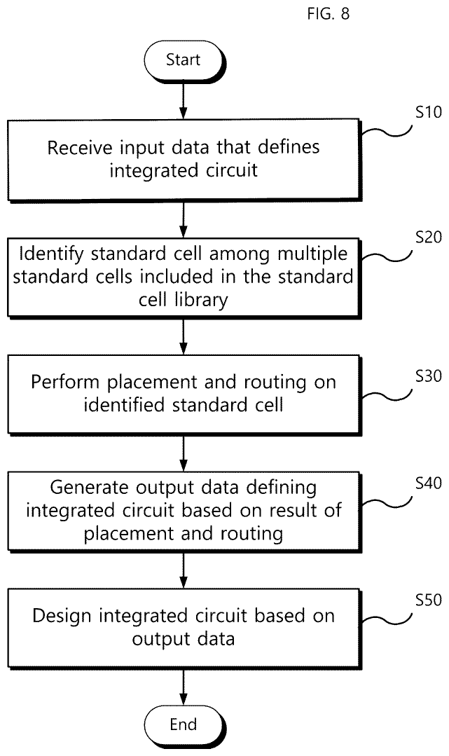

FIG. 8 is a flowchart illustrating an example of an operation of a semiconductor device of FIG. 7 according to some example embodiments.

Referring to FIG. 8, the processor 710 according to some example embodiments may design an integrated circuit using a standard cell included in the standard cell library 721. For example, the processor 710 may design an integrated circuit by executing a plurality of instructions stored in the memory 720.

In operation S10, the processor 710 may receive input data defining an integrated circuit. For example, the processor 710 may receive the input data from the memory 720.

In some example embodiments, the input data may be understood as data defining an integrated circuit including a standard cell according to the some example embodiments.

For example, the input data may be understood as data defining a layout of the integrated circuit. The input data may include geometric information defining structures implemented as semiconductor materials, metals, insulators, etc. The layout of the integrated circuit indicated by the input data may include a layout of standard cells and may include conductive lines connecting the standard cells to each other.

In some example embodiments, the input data may be data generated by synthesis from an abstract form for the behavior of an integrated circuit, for example, from data defined at a register transfer level (RTL). The input data may be a bitstream or a netlist generated by synthesizing integrated circuits defined as VHSIC Hardware Description Language (VHDL) and Hardware Description Language (HDL) such as Verilog, but example embodiments are not limited thereto.

In some example embodiments, the input data may further include the standard cell library 721 stored in the memory 720.

In operation S20, the processor 710 may identify at least one standard cell among a plurality of standard cells included in the standard cell library 721 based on the input data.

For example, the processor 710 may identify at least one standard cell forming an integrated circuit defined by input data from among a plurality of standard cells included in the standard cell library 721.

In some example embodiments, the identified standard cell may be referred to as the standard cell 100A of FIG. 1B.

The standard cell identified according to some example embodiments may include the first region 101 and the second region 102 that are distinguished from each other.

For example, the first region 101 may include the first PMOS region 111 and the first NMOS region 121 formed to have the first width W1. Furthermore, the first region 101 may include at least one transistor including a first channel having the first width W1.

In some example embodiments, the second region 102 may include the second PMOS region 112 and the second NMOS region 122 having the second width W2 greater than the first width W1. Furthermore, the second region 102 may include at least one transistor including a second channel having the second width W2.

For example, the standard cells may include a plurality of transistors having different channel widths and disposed on the distinct regions (e.g., the first region 101 and the second region 102). In some example embodiments, the first region 101 and the second region 102 may have the same width (or height) in the designated direction.

In operation S30, the processor 710 may perform placement and routing on the identified at least one standard cell.

For example, the processor 710 may place the identified at least one standard cell with respect to the integrated circuit defined by the input data using the placement unit 711. In some example embodiments, the processor 710 may perform signal routing on the arrangement of standard cells provided from the placement unit 711 by using the routing unit 712.

In some example embodiments, the signal routing may include an operation of setting a connection path of a signal between standard cells arranged by the placement unit 711 or elements included in the standard cell.

Furthermore, in operation S40, the processor 710 may generate output data defining an integrated circuit based on a result of the placement of the placement unit 711 and the routing result of the routing unit 712.

In some example embodiments, the output data may have a format corresponding to the input data. For example, when the received input data is data such as a bitstream or netlist generated by synthesizing an integrated circuit, the output data may be a bitstream or netlist. In some example embodiments, when the received input data is data defining the layout of an integrated circuit having the GDSII (Graphic Data System II) format, the output data may also be data that defines the layout of the integrated circuit having the same format as the input data.

In some example embodiments, in operation S50, the semiconductor device 700 may design an integrated circuit based on the output data. Accordingly, in some example embodiments, the semiconductor device 700 may design an integrated circuit using a standard cell in which a plurality of transistors having different channel widths and operating characteristics are disposed in different regions.

In some example embodiments, the semiconductor device 700 may configure elements constituting an integrated circuit with transistors formed to have different channel widths according to respective operating characteristics in a standard cell.

Through this, the semiconductor device 700 according to some example embodiments may improve the performance of the integrated circuit.

As described above, the standard cell 100 according to some example embodiments may include transistors having different channel widths and disposed in distinct regions. For example, transistors having the same channel width and disposed in the same region may be formed to be adjacent to each other.

Through this, the standard cell 100 according to some example embodiments may prevent performance deterioration of transistors caused by transistors having different channel widths being formed adjacent to each other.

According to some example embodiments, the semiconductor device 700 may improve performance of an integrated circuit designed through the standard cell 100.

According to some example embodiments, the standard cell 100 may include transistors having different channel widths and disposed separately in regions 101 and 102 having the same width (or height).

Through this, the standard cell 100 may reduce at least some of the time, cost, and power required for designing the standard cell 100 or an integrated circuit including the standard cell 100.

According to some example embodiments, the standard cell 100 may include transistors having different operating characteristics due to different channel widths in distinct regions.

Through this, the standard cell 100 may control regions that are distinguished from each other depending on the characteristics of the transistors. In some example embodiments, the standard cell 100 may increase control efficiency of a plurality of transistors.

According to some example embodiments, a standard cell may include transistors having different channel widths and formed in distinct regions. Accordingly, the standard cell may prevent performance deterioration of the transistors.

As described herein, any devices electronic devices, modules, models, units, and/or portions thereof according to any of the example embodiments, and/or any portions thereof may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), a programmable logic unit, a microprocessor, application-specific integrated circuit (ASIC), a neural network processing unit (NPU), an Electronic Control Unit (ECU), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, electronic devices, modules, units, and/or portions thereof according to any of the example embodiments.

Example embodiments in which a design is changed simply or which are easily changed may be included in the present inventive concepts as well as the example embodiments described above. In addition, technologies that are easily changed and implemented using the above example embodiments may be included in the present inventive concepts. While the present inventive concepts have been described with reference to some example embodiments thereof, it will be apparent to those of ordinary skill in the art that various changes and modifications could be made without departing from the spirit and scope of the present inventive concepts as set forth in the following claims.

What is claimed is:

1. A standard cell including a plurality of regions, comprising:
a first region including a first active region extending in a first direction and having a first width;
a second region including a second active region extending in the first direction and having a second width greater than the first width; and
a first gate electrode extending in a second direction perpendicular to the first direction,
wherein a first transistor corresponding to at least a portion of the first active region and the first gate electrode includes a first channel having the first width,
wherein a second transistor corresponding to at least a portion of the second active region and the first gate electrode includes a second channel having the second width, and
wherein the first region and the second region contact in the second direction and have the same width with respect to the second direction.

2. The standard cell of claim 1, wherein the first transistor includes a first nanosheet having the first width and corresponds to the first channel, and
wherein the second transistor includes a second nanosheet having the second width and corresponds to the second channel.

3. The standard cell of claim 2, wherein the first nanosheet is surrounded by the first gate electrode in a region of the first gate electrode corresponding to the first active region, and
wherein the second nanosheet is surrounded by the first gate electrode in a region of the first gate electrode corresponding to the second active region.

4. The standard cell of claim 1, wherein the second transistor operates at a second speed higher than a first speed of the first transistor, and operates with a second power greater than a first power of the first transistor.

5. The standard cell of claim 1, wherein the first transistor corresponds to a first source-drain region corresponding to both sides of the first gate electrode in the first active region and the first gate electrode, and
wherein the second transistor corresponds to a second source-drain region corresponding to the both sides of the first gate electrode in the second active region and the first gate electrode.

6. The standard cell of claim 1, further comprising:
a first power line extending in the first direction from an edge in which the first region and the second region contact each other;
a second power line extending in the first direction from an edge of the first region parallel to an edge adjacent to the second region; and
a third power line extending in the first direction from an edge of the second region parallel to an edge adjacent to the first region, and
wherein the second power line and the third power line apply the same voltage to at least a portion of the first region and the second region, respectively.

7. The standard cell of claim 6, wherein the first active region includes a first PMOS region and a first NMOS region spaced apart from each other in the second direction,
the second active region includes a second PMOS region and a second NMOS region spaced apart from each other in the second direction,
the first NMOS region and the second NMOS region are adjacent to the first power line,
the first PMOS region is adjacent to the second power line, and
the second PMOS region is adjacent to the third power line.

8. The standard cell of claim 4, further comprising:
a second gate electrode parallel to the first gate electrode, and
wherein a portion of the first active region and the second gate electrode correspond to a third transistor, and
wherein the third transistor includes a third channel having the first width and is adjacent to the first transistor.

9. The standard cell of claim 8, wherein the third transistor includes a third nanosheet having the first width and corresponds to the third channel, and
wherein the third nanosheet is surrounded by the second gate electrode in a region of the second gate electrode corresponding to the first active region.

10. The standard cell of claim 1, wherein the first region has a first height in the first direction, and
wherein the second region has a second height greater than the first height in the first direction.

11. An integrated circuit including a standard cell comprising:
a first power line extending in a first direction;
a second power line and a third power line extending in the first direction and spaced apart from the first power line by a first distance in a second direction perpendicular to the first direction; and
a standard cell including regions between the first power line, the second power line, and the third power line,
wherein the standard cell includes:
a first active region extending in the first direction and having a first width in a first region between the first power line and the second power line;
a second active region extending in the first direction and having a second width greater than the first width in a second region between the first power line and the third power line; and
a first gate electrode extending in the second direction,
wherein a first transistor corresponding to at least a portion of the first active region and the first gate electrode includes a first channel having the first width, and
wherein a second transistor corresponding to at least a portion of the second active region and the first gate electrode includes a second channel having the second width.

12. The integrated circuit of claim 11, wherein the first transistor includes a first nanosheet having the first width in a region of the first gate electrode corresponding to the first active region,
wherein the second transistor includes a second nanosheet having the second width in a region of the first gate electrode corresponding to the second active region, and
wherein the first nanosheet and the second nanosheet are surrounded by the first gate electrode.

13. The integrated circuit of claim 11, wherein the second transistor operates at a second speed higher than a first speed of the first transistor, and operates with a second power greater than a first power of the first transistor.

14. The integrated circuit of claim 11, wherein the first transistor corresponds to a first source-drain region corresponding to both sides of the first gate electrode in the first active region and the first gate electrode, and
wherein the second transistor corresponds to a second source-drain region corresponding to the both sides of the first gate electrode in the second active region and the first gate electrode.

15. The integrated circuit of claim 11, wherein the first power line, the second power line, and the third power line apply one of a drain voltage and a source voltage to the first region and at least a portion of the second region, and
wherein the second power line and the third power line apply the same voltage to the first region and the second region.

16. The integrated circuit of claim 11, wherein the first active region includes a first PMOS region and a first NMOS region spaced apart from each other in the second direction,
the second active region includes a second PMOS region and a second NMOS region spaced apart from each other in the second direction,
the first NMOS region and the second NMOS region are adjacent to the first power line,
the first PMOS region is adjacent to the second power line, and
the second PMOS region is adjacent to the third power line.

17. The integrated circuit of claim 11, further comprising:
a second gate electrode parallel to the first gate electrode and crossing the first region and the second region, and
wherein a portion of the first active region and the second gate electrode correspond to a third transistor, and
wherein the third transistor includes a third channel having the first width and is adjacent to the first transistor.

18. The integrated circuit of claim 17, wherein the third transistor includes a third nanosheet having the first width and corresponds to the third channel, and
wherein the third nanosheet is surrounded by the second gate electrode in a region of the second gate electrode corresponding to the first active region.

19. The integrated circuit of claim 11, wherein the first region has a first height in the first direction, and
wherein the second region has a second height greater than the first height in the first direction.

20. A method of designing an integrated circuit including a standard cell, the method comprising:
receiving input data defining the integrated circuit;
identifying at least one standard cell among a plurality of standard cells included in a standard cell library based on the input data;
performing placement and routing on the identified at least one standard cell based on the input data;
generating output data defining the integrated circuit based on a result of the placement and routing; and
designing the integrated circuit based on the output data,
wherein the at least one standard cell includes:
a first region including a first active region extending in a first direction and having a first width;
a second region including a second active region extending in the first direction and having a second width greater than the first width; and
a first gate electrode extending in a second direction perpendicular to the first direction,
wherein a first transistor formed by the first gate electrode and at least a portion of the first active region includes a first channel having the first width,
wherein a second transistor formed by the first gate electrode and at least a portion of the second active region includes a second channel having the second width, and
wherein the first region and the second region contact in the second direction and have the same width with respect to the second direction.
